(19) United States
(12) Patent Application Publication
(10) Pub. No.: US 2025/0309617 A1
(43) Pub. Date: Oct. 2, 2025

(54) SURFACE EMITTING SEMICONDUCTOR LASER AND OPTICAL TRANSMISSION APPARATUS

(71) Applicant: FUJIFILM Business Innovation Corp., Tokyo (JP)

(72) Inventors: Yuto IWANE, Kanagawa (JP); Takeshi MINAMIRU, Kanagawa (JP); Koga MIZUNO, Kanagawa (JP); Tsutomu HAMADA, Kanagawa (JP); Hideki FUKUNAGA, Kanagawa (JP); Akemi MURAKAMI, Kanagawa (JP); Hideo NAKAYAMA, Kanagawa (JP); Kazutaka TAKEDA, Kanagawa (JP)

(73) Assignee: FUJIFILM Business Innovation Corp., Tokyo (JP)

(21) Appl. No.: 18/800,510

(22) Filed: Aug. 12, 2024

(30) Foreign Application Priority Data
Mar. 27, 2024 (JP) 2024-052305

(51) Int. Cl. H01S 5/343; H01S 5/183; H01S 5/34

(52) U.S. Cl. CPC H01S 5/34313; H01S 5/18369; H01S 5/3407

(57) ABSTRACT

A surface emitting semiconductor laser includes a substrate; a first semiconductor multilayer film reflective mirror stacked on the substrate; a second semiconductor multilayer film reflective mirror that includes a current confinement layer and is stacked on the first semiconductor multilayer film reflective mirror; and a light emitting layer that is disposed between the first semiconductor multilayer film reflective mirror and the second semiconductor multilayer film reflective mirror, emits light, and is configured by alternately stacking a quantum well layer containing at least In, Ga, and As and a barrier layer, in which a thickness of the quantum well layer is thinner than a critical film thickness by a predetermined margin.

### CROSS-REFERENCE TO RELATED APPLICATIONS

This application is based on and claims priority under 35 USC 119 from Japanese Patent Application No. 2024-052305 filed Mar. 27, 2024.

### BACKGROUND

### (i) Technical Field

The present disclosure relates to a surface emitting semiconductor laser and an optical transmission apparatus.

### (ii) Related Art

JP2008-244470A discloses a surface emitting laser element including a substrate, an optical resonator that is located on the substrate and includes a lower multilayer film reflective mirror and an upper multilayer film reflective mirror, a strained active layer that is located in the resonator and has a multiple quantum well structure of including a quantum well layer and a barrier layer, and a current confinement layer that is located on an upper side of the strained active layer and has a selective oxidation portion, in which the current confinement layer is disposed at a position at which an influence of the strain in the selective oxidation portion is exerted on the strained active layer.

### SUMMARY

Aspects of non-limiting embodiments of the present disclosure relate to a surface emitting semiconductor laser and an optical transmission apparatus that make a quantum well layer containing at least In, Ga, and As in a multilayer structure in a light emitting layer configured by alternately stacking the quantum well layer and a barrier layer, as compared with a case where a thickness of the quantum well layer increases to be close to a critical film thickness and the barrier layer is made to have a thickness according to the thickness of the quantum well layer.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a surface emitting semiconductor laser including a substrate; a first semiconductor multilayer film reflective mirror stacked on the substrate; a second semiconductor multilayer film reflective mirror that includes a current confinement layer and is stacked on the first semiconductor multilayer film reflective mirror; and a light emitting layer that is disposed between the first semiconductor multilayer film reflective mirror and the second semiconductor multilayer film reflective mirror, emits light, and is configured by alternately stacking a quantum well layer containing at least In, Ga, and As and a barrier layer, in which a thickness of the quantum well layer is thinner than a critical film thickness by a predetermined margin.

### BRIEF DESCRIPTION OF THE DRAWINGS

Exemplary embodiment(s) of the present invention will be described in detail based on the following figures, wherein:

FIG. 1 is a cross-sectional view showing a surface emitting semiconductor laser according to an exemplary embodiment of the present disclosure;

FIG. 2 is an enlarged cross-sectional view around an active layer of the surface emitting semiconductor laser shown in FIG. 1;

FIG. 3 is a graph showing a relationship between an indium composition ratio and a thickness of a quantum well layer; and

FIG. 4 is a graph showing a relationship between a thickness of a barrier layer in a light emitting layer and an optical confinement coefficient.

### DETAILED DESCRIPTION

Hereinafter, an exemplary embodiment for carrying out the technique of the present disclosure will be described in detail with reference to the drawings. Components and processing having identical operations, actions, and functions are designated by identical reference signs throughout the drawings, and redundant descriptions may be omitted as appropriate. Each drawing is merely schematically shown to the extent that the technology of the present disclosure can be fully understood. Thus, the technique of the present disclosure is not limited to only the shown examples. In addition, in the present exemplary embodiment, descriptions of configurations that are not directly related to the technology of the present disclosure and of well-known configurations may be omitted.

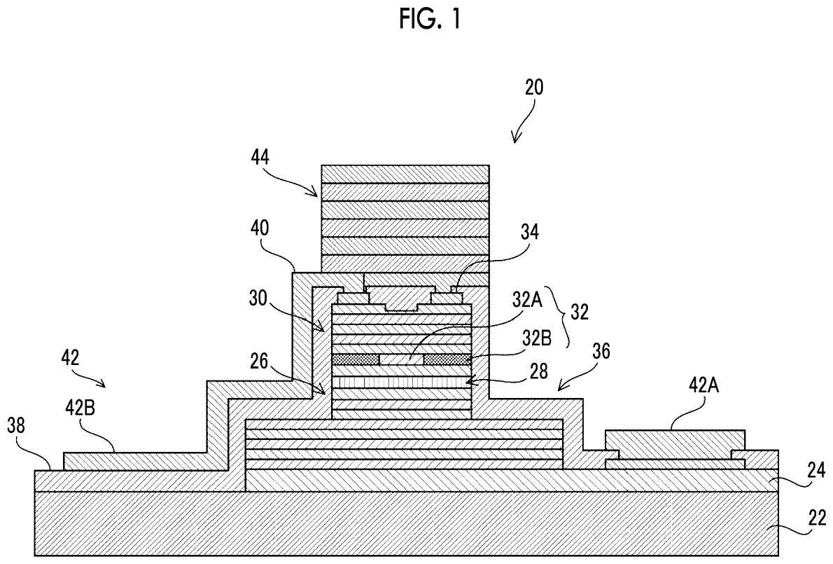

FIG. 1 is a cross-sectional view showing a surface emitting semiconductor laser 20 according to an exemplary embodiment of the present disclosure.

As shown in FIG. 1, the surface emitting semiconductor laser 20 according to the present exemplary embodiment is, for example, a vertical cavity surface emitting laser (VCSEL).

As shown in FIG. 1, the surface emitting semiconductor laser 20 according to the present exemplary embodiment includes a substrate 22, a contact layer 24, a first semiconductor multilayer film reflective mirror 26, an active layer 28, and a second semiconductor multilayer film reflective mirror 30.

In the present exemplary embodiment, the first semiconductor multilayer film reflective mirror 26 is an n-type, and the second semiconductor multilayer film reflective mirror 30 is a p-type. The present disclosure is not limited to this configuration.

In the surface emitting semiconductor laser 20 according to the present exemplary embodiment, each configuration including the contact layer 24, the first semiconductor multilayer film reflective mirror 26, the active layer 28, the second semiconductor multilayer film reflective mirror 30, and the dielectric multilayer film reflective mirror 44 forms a mesa structural body 36. The mesa structural body 36 constitutes a laser portion of the surface emitting semiconductor laser 20.

The substrate 22 is, for example, a semi-insulating gallium arsenide (GaAs) substrate. The semi-insulating GaAs substrate is a GaAs substrate in which impurities are not doped. The semi-insulating GaAs substrate has a very high resistivity, and, for example, a sheet resistance value of the substrate shows a value of approximately several MQ.

A material of the substrate 22 may be a material other than GaAs, and for example, gallium nitride (GaN) or indium phosphide (InP) may be used.

The contact layer 24 is stacked on the substrate 22. The contact layer 24 is formed of, for example, an n-type GaAs layer doped with Si.

The contact layer 24 is connected to the n-type first semiconductor multilayer film reflective mirror 26. An electrode pad 42B on an n side is formed at the contact layer 24. Therefore, the contact layer 24 has a function of applying a negative potential to the laser portion configured by the mesa structural body 36.

The contact layer 24 may double as a buffer layer that is provided to achieve favorable crystallinity of the substrate surface after thermal cleaning, for example.

The n-type first semiconductor multilayer film reflective mirror 26 is stacked on the contact layer 24. The first semiconductor multilayer film reflective mirror 26 constitutes a lower distributed Bragg reflector (DBR).

The first semiconductor multilayer film reflective mirror 26 is a multilayer film reflective mirror configured by alternately and repeatedly stacking two semiconductor films having different refractive indexes from each other. Specifically, the first semiconductor multilayer film reflective mirror 26 is configured by alternately and repeatedly stacking a low refractive index film of the n-type based on Al_{0.92}GaAs and a high refractive index film of the n-type based on GaAs. A refractive index of n-type Al_{0.92}GaAs is lower than a refractive index of n-type GaAs.

The active layer 28 is stacked on the first semiconductor multilayer film reflective mirror 26. The active layer 28 functions as a resonator. The details of the active layer 28 will be described later.

The p-type second semiconductor multilayer film reflective mirror 30 is stacked on the active layer 28. In other words, the second semiconductor multilayer film reflective mirror 30 is stacked on the first semiconductor multilayer film reflective mirror 26 with the active layer 28 interposed between the second semiconductor multilayer film reflective mirror 30 and the first semiconductor multilayer film reflective mirror 26. The second semiconductor multilayer film reflective mirror 30 constitutes an upper DBR.

The second semiconductor multilayer film reflective mirror 30 is a multilayer film reflective mirror configured by alternately and repeatedly stacking two semiconductor films having different refractive indexes from each other. Specifically, the second semiconductor multilayer film reflective mirror 30 is configured by alternately and repeatedly stacking a low refractive index film of the p-type based on Al_{0.92}GaAs and a high refractive index film of the p-type based on GaAs. A refractive index of p-type Al_{0.92}GaAs is lower than a refractive index of p-type GaAs.

In addition, the second semiconductor multilayer film reflective mirror 30 includes a selective oxidation layer 32. The selective oxidation layer 32 is an example of a current confinement layer. The selective oxidation layer 32 is disposed above the active layer 28. The selective oxidation layer 32 includes an aperture 32A representing a portion that is not subjected to oxidation confinement and an oxidation-confined region 32B that is a region subjected to oxide confinement.

In addition to selective oxidation of current confinement, for example, current confinement may be performed by temporarily forming a pattern corresponding to an opening portion in stacking a layered structure to selectively make a current easily pass to the opening portion or by performing ion implantation to make the current have difficulty in passing to a portion subjected to ion implantation.

An amount of aluminum per unit amount of an aluminum-containing material forming the selective oxidation layer 32 may be more than an amount of aluminum per unit amount of an aluminum-containing material forming the second semiconductor multilayer film reflective mirror 30. The selective oxidation layer 32 is formed of, for example, aluminum arsenide (AlAs) or Al_{0.98}GaAs.

An interlayer insulating film 38 as an inorganic insulating film is deposited around the semiconductor layer including the mesa structural body 36. The interlayer insulating film 38 is stretched from the side surface of the mesa structural body 36 to the surface of the substrate 22. In addition, the interlayer insulating film 38 is disposed below an electrode pad 42A.

The interlayer insulating film 38 is formed of, for example, a silicon nitride film (SiN film). A material of the interlayer insulating film 38 is not limited to the silicon nitride film, and, for example, a silicon oxide film (SiO₂ film) or a silicon oxynitride film (SiON film) may be used.

A wiring 40 is provided on the interlayer insulating film 38. One end side of the wiring 40 is connected to the contact metal 34 which will be described below. On the other hand, the other end side of the wiring 40 is stretched from the contact metal 34 to the surface of the substrate 22 through the side surface of the mesa structural body 36 on the interlayer insulating film 38. In addition, the electrode pad 42A on a p side is formed by a portion of the interlayer insulating film 38 located on the surface of the substrate 22.

The contact metal 34 is provided on the second semiconductor multilayer film reflective mirror 30. The contact metal 34 is connected to the wiring 40. For example, a stacked film of Ti/Au may be used as the contact metal 34. In addition, the contact metal 34 in the present exemplary embodiment has a cross-sectional shape that is rectangular and annular, as an example.

In addition, the dielectric multilayer film reflective mirror 44 is stacked on the contact metal 34. The dielectric multilayer film reflective mirror 44 may be included in the upper DBR.

The dielectric multilayer film reflective mirror 44 is a multilayer film reflective mirror configured by alternately and repeatedly stacking two dielectric films having different refractive indexes from each other. Specifically, the dielectric multilayer film reflective mirror 44 is configured by alternately and repeatedly stacking a high refractive index film formed of tantalum pentoxide (Ta₂O₅) and a low refractive index film formed by silicon oxide film (SiO₂ film).

Next, the details of the active layer 28 will be described.

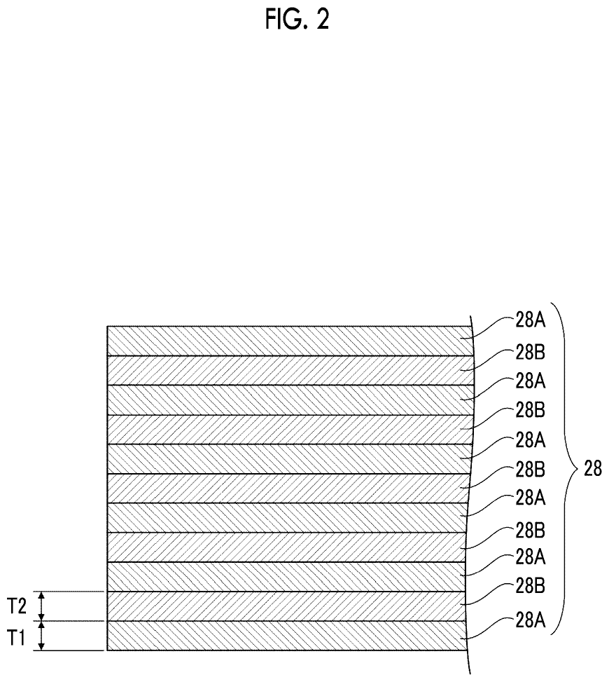

FIG. 2 is an enlarged cross-sectional view around the active layer 28 of the surface emitting semiconductor laser 20 shown in FIG. 1.

As shown in FIG. 2, the active layer 28 is an example of a light emitting layer that is disposed between the first semiconductor multilayer film reflective mirror 26 and the second semiconductor multilayer film reflective mirror 30 and emits light.

The active layer 28 is configured by alternately and repeatedly stacking the quantum well layer 28A and the barrier layer 28B.

The quantum well layer 28A is a layer containing at least In, Ga, and As. In the present exemplary embodiment, for example, the quantum well layer 28A is a layer configured with InGaAs (indium gallium arsenide).

The barrier layer 28B is a layer configured with GaAs, for example.

The active layer 28 is configured by alternately and repeatedly stacking an InGaAs film constituting the quantum well layer 28A and a GaAs film constituting the barrier layer 28B.

A thickness T1 of the quantum well layer 28A is thinner than a critical film thickness T0 by a predetermined margin M. The margin M is, for example, preferably equal to or more than 4.0 nm, and more preferably equal to or more than 4.4 nm.

The “critical film thickness” referred to in the present exemplary embodiment is based on the theoretical value of Matthews-Blakeslee.

In addition, the thickness T1 of the quantum well layer 28A is preferably, for example, within +30% of a thickness of the barrier layer 28B.

In addition, the thickness T1 of the quantum well layer 28A is preferably, for example, thinner than a thickness T2 of the barrier layer 28B. That is, the thickness T1 of the quantum well layer 28A is set to be thin, more preferably, for example, in a range of more than 0% and equal to or less than 30% with respect to the thickness T2 of the barrier layer 28B.

For example, the thickness T2 of the barrier layer 28B is equal to or less than the critical film thickness TO, and is preferably equal to or more than 4.0 nm.

The In (indium) composition of the quantum well layer 28A is preferably, for example, equal to or more than 28%.

Next, the operational effects of the present exemplary embodiment will be described.

In a case where the substrate 22 is basically formed of GaAs, and InGaAs having a high indium composition is selected as the material of the quantum well layer 28A, crystal strain due to lattice mismatch increases. In order to suppress the propagation of dislocation due to the increase in crystal strain, in a case where the thickness of the barrier layer 28B is increased, it is difficult to make the quantum well layer 28A in a multilayer structure in the active layer 28, and it is also difficult to increase the optical confinement coefficient. On the other hand, it has been found that the thickness T2 of the barrier layer 28B can be also reduced by reducing the thickness T1 of the quantum well layer 28A having an increased indium composition from the critical film thickness T0 by the predetermined margin M.

In the surface emitting semiconductor laser 20 according to the present exemplary embodiment, as described above, the thickness T 1 of the quantum well layer 28A is thinner than the critical film thickness T0 by the predetermined margin M. Therefore, in the surface emitting semiconductor laser 20, as compared with a case where the thickness T1 of the quantum well layer 28A is increased to be close to the critical film thickness T0 and the barrier layer 28B is made to have the thickness T2 according to the thickness T1 of the quantum well layer 28A, it is possible to reduce the thickness T2 of the barrier layer 28B and to make the quantum well layer 28A in a multilayer structure in the active layer 28. Then, the optical confinement coefficient is increased by making the quantum well layer 28A in a multilayer structure in the active layer 28.

In addition, in the surface emitting semiconductor laser 20 according to the present exemplary embodiment, by setting the margin M to be equal to or more than 4.0 nm, for example, preferably, equal to or more than 4.4 nm, it is possible to make the quantum well layer 28A in a multilayer structure in the active layer 28.

In addition, in the surface emitting semiconductor laser 20 according to the present exemplary embodiment, since the In composition of the quantum well layer 28A is set to be equal to or more than 28%, for example, the margin M between the critical film thickness TO and the thickness T1 of the quantum well layer 28A is easily secured as compared with a case where the In composition of the quantum well layer 28A is less than 28%. In addition, in the active layer 28 applied to the surface emitting semiconductor laser 20 in the present exemplary embodiment, by setting the In composition of the quantum well layer 28A to be equal to or more than 28%, it is possible to reduce both the thickness T1 of the quantum well layer 28A and the thickness T2 of the barrier layer 28B, and to secure the mPL (photoluminescence) light emission intensity of the active layer 28.

In addition, in the surface emitting semiconductor laser 20 according to the present exemplary embodiment, in a case where the thickness T1 of the quantum well layer 28A is set to be within +30% of the thickness of the barrier layer 28B, as compared with a case where the thickness T1 of the quantum well layer 28A is more than +30% and less than −30% of the thickness T2 of the barrier layer 28B, it is possible to secure the PL light emission intensity by the active layer 28 while suppressing coupling between the adjacent quantum well layers 28A.

In addition, in the surface emitting semiconductor laser 20 according to the present exemplary embodiment, in a case where the thickness T1 of the quantum well layer 28A is set to be thinner than the thickness T2 of the barrier layer 28B, it is possible to suppress the increase in crystal strain due to lattice mismatch as compared with a case where the thickness T1 of the quantum well layer 28A is thicker than the thickness T2 of the barrier layer 28B. That is, by setting the thickness T1 to be thinner than the thickness T2, it is possible to suppress the propagation of dislocation due to the increase in crystal strain. In a case where the thickness T1 of the quantum well layer 28A is set to be thin in a range of more than 0% and equal to or less than 30% with respect to the thickness T2 of the barrier layer 28B, it is possible to secure the PL light emission intensity by the active layer 28 while suppressing the coupling between the adjacent quantum well layers 28A, and to further suppress the propagation of dislocation due to the increase in crystal strain.

In addition, in the surface emitting semiconductor laser 20 according to the present exemplary embodiment, the thickness T2 of the barrier layer 28B is equal to or less than the critical film thickness T0 and equal to or more than 4.0 nm. Therefore, in the surface emitting semiconductor laser 20, it is possible to make the quantum well layer 28A in a multilayer structure in the active layer 28 as compared with a case where the thickness T2 of the barrier layer 28B is more than the critical film thickness T0 of the quantum well layer 28A. In addition, in the surface emitting semiconductor laser 20, it is possible to suppress the coupling between the adjacent quantum well layers 28A as compared with a case where the thickness T2 of the barrier layer 28B is less than 4.0 nm.

In addition, in the surface emitting semiconductor laser 20 according to the present exemplary embodiment, the quantum well layer 28A is an InGaAs quantum well layer.

Therefore, in the surface emitting semiconductor laser 20, the margin M between the critical film thickness T0 and the thickness T1 of the quantum well layer 28A is easily secured as compared to a case of containing a component other than InGaAs.

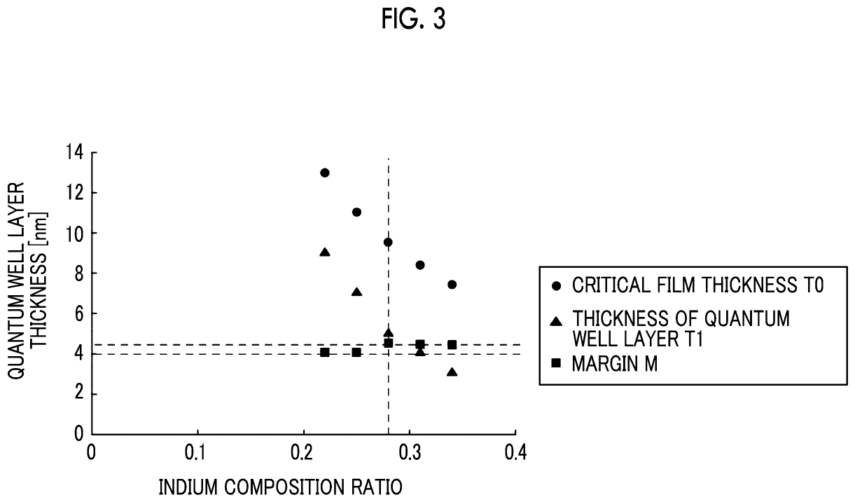

Table 1 and FIG. 3 show the relationship between the indium composition of the quantum well layer 28A, the thickness T1 of the quantum well layer 28A, the critical film thickness TO, and the margin M in a case where laser light having a wavelength of 1060 nm is obtained from the surface emitting semiconductor laser 20 in the present exemplary embodiment below.

In Table 1, a case where the relationship of 4.0 nm≤ the thickness T2 of the barrier layer 28B< the critical film thickness T0 of the quantum well layer 28A can be established is determined as “A”, and a case where the relationship of the thickness T2 of the barrier layer 28B< the critical film thickness T0 of the quantum well layer 28A can be established but it is not possible to reduce the thickness T2 to 4.0 nm is determined as “B”.

TABLE 1

| | Thickness | Critical | | |
|---|---|---|---|---|
| | T1 [nm] of | Film | | |
| In Composition | Quantum | Thickness | Margin M | |
| [%] | Well Layer | T0 [nm] | [nm] | Determination |
| 22 | 9 | 13.0 | 4.0 | B |
| 25 | 7 | 11.0 | 4.0 | B |
| 28 | 5 | 9.5 | 4.5 | A |
| 31 | 4 | 8.4 | 4.4 | A |
| 34 | 3 | 7.4 | 4.4 | A |

By setting the thickness T1 of the quantum well layer 28A to have a margin M that is equal to or more than 4.0 nm with respect to the critical film thickness T0 based on Table 1 and FIG. 3, and setting the thickness T2 of the barrier layer 28B according to the thickness T1, it is possible to set the thickness T1 to be close to the critical film thickness TO, and to reduce the thickness T2 of the barrier layer 28B as compared with a case where the thickness T2 is set according to the thickness T1. As a result, it is possible to make the quantum well layer 28A in a multilayer structure in the active layer 28.

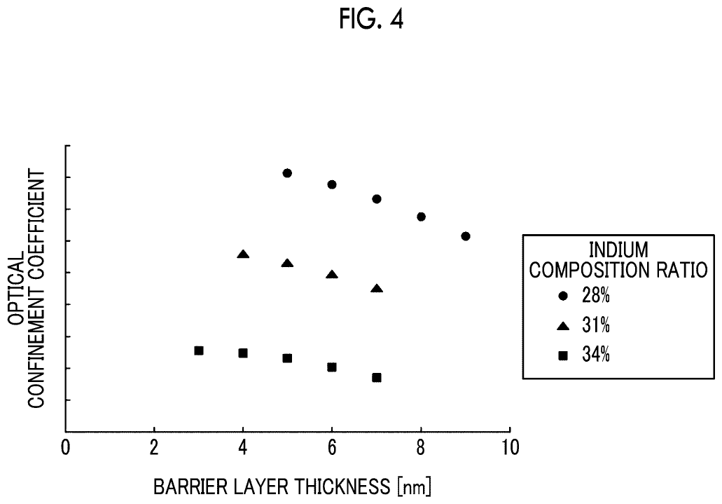

In addition, FIG. 4 shows a graph in which the relationship between the thickness T2 of the barrier layer 28B and the optical confinement coefficient, which is obtained by the simulation. As shown in FIG. 4, it can be seen that, in any In composition, as the thickness T2 of the barrier layer 28B becomes thinner, the multilayer structure of the quantum well layer 28A in the active layer 28 advances, and the optical confinement coefficient increases.

The exemplary embodiment of the surface emitting semiconductor laser 20 has been described above. The exemplary embodiment may be in the form of an optical transmission apparatus including the surface emitting semiconductor laser 20. The optical transmission apparatus includes an optical transmission unit (not shown) that transmits light output from the surface emitting semiconductor laser 20. In such an optical transmission apparatus, it is possible to increase an optical transmission speed as compared with a case of using a surface emitting semiconductor laser having a configuration in which the thickness T1 of the quantum well layer 28A is increased to be close to the critical film thickness T0 and the barrier layer 28B is made to have the thickness according to the thickness T1 of the quantum well layer 28A.

In the above exemplary embodiment, the dielectric multilayer film reflective mirror 44 is disposed on the first semiconductor multilayer film reflective mirror 26, but the present disclosure is not limited to this configuration. The dielectric multilayer film reflective mirror 44 may be omitted, and the reflectivity required for the upper DBR may be configured only by the second semiconductor multilayer film reflective mirror 30. In this manner, it is easy to obtain layer oscillation having the compensated reflectivity that is not sufficient only by omitting the dielectric multilayer film reflective mirror from the VCSEL structure using the dielectric multilayer film reflective mirror.

In addition, in the above exemplary embodiment, the surface emitting semiconductor laser based on GaAs using the semi-insulating GaAs substrate has been described as an example. The present disclosure is not limited to this and may be in the form of using a substrate based on gallium nitride (GaN) or a substrate based on indium phosphide (InP). In a case where the material of the substrate is changed, it is necessary to appropriately set the material and a confinement method of the substrate material. For example, in the case of a GaN substrate, a pair of aluminum gallium nitride (AlGaN) and GaN may be used for a lower DBR which will be described later, a pair of an indium gallium nitride (InGaN) quantum well layer and a GaN barrier layer may be used for an active layer, and a dielectric DBR may be used for an upper DBR.

In addition, for example, in the case of an InP substrate, a pair of InGaAsP having a different composition may be used for a lower DBR, an InGaAsP quantum well layer and a barrier layer having different compositions may be used for an active layer, and a dielectric DBR may be used for an upper DBR.

In addition, in a case where a GaN substrate and an InP substrate are used, it is not possible to use a material capable of selective oxidation and to perform oxidation confinement. Thus, for example, current confinement by an embedded tunnel junction may be used.

In addition, while the form of forming the contact layer of the n-type on the substrate has been described as an example in the above exemplary embodiment, the present disclosure is not limited to this and may be in the form of forming a contact layer of the p-type on the substrate. In this case, the n-type and the p-type may be replaced with each other in reverse in the above description.

In addition, in the above exemplary embodiment, the surface emitting semiconductor laser in which InGaAs is used for the quantum well layer 28A and GaAs is used for the barrier layer 28B has been clearly described, but the present disclosure is not limited to this. A form in which InAlGaAs is used for the quantum well layer 28A and AlGaAs, GaAsP, or the like is used for the barrier layer may be made.

The present disclosure is not limited to the above description, and can be variously modified and implemented in a range without departing from the gist of the present invention.

Regarding the above exemplary embodiments, the following supplementary notes will be further disclosed.

(((1)))

A surface emitting semiconductor laser comprising:
a substrate;
a first semiconductor multilayer film reflective mirror stacked on the substrate;
a second semiconductor multilayer film reflective mirror that includes a current confinement layer and is stacked on the first semiconductor multilayer film reflective mirror; and
a light emitting layer that is disposed between the first semiconductor multilayer film reflective mirror and the second semiconductor multilayer film reflective mirror, emits light, and is configured by alternately stacking a quantum well layer containing at least In, Ga, and As and a barrier layer, in which a thickness of the quantum well layer is thinner than a critical film thickness by a predetermined margin.
   (((2)))

The surface emitting semiconductor laser according to (((1))),
wherein a thickness of the barrier layer is equal to or less than the critical film thickness.
   (((3)))

The surface emitting semiconductor laser according to (((1))),
wherein the margin is equal to or more than 4.0 nm.
   (((4)))

The surface emitting semiconductor laser according to(((3))),
wherein the margin is equal to or more than 4.4 nm.
   (((5)))

The surface emitting semiconductor laser according to any one of (((1))) to (((4))),
wherein an In composition of the quantum well layer is equal to or more than 28%.
   (((6)))

The surface emitting semiconductor laser according to any one of (((1))) to (((5))),
wherein the thickness of the quantum well layer is thinner than a thickness of the barrier layer.
   (((7)))

The surface emitting semiconductor laser according to (((2))),
wherein the thickness of the barrier layer is equal to or more than 4.0 nm.
   (((8)))

The surface emitting semiconductor laser according to any one of (((1))) to (((5))),
wherein the thickness of the quantum well layer is within +30% of a thickness of the barrier layer.
   (((9)))

The surface emitting semiconductor laser according to any one of (((1))) to (((8))),
wherein the quantum well layer is an InGaAs quantum well layer.
   (((10)))

An optical transmission apparatus comprising:
the surface emitting semiconductor laser according to any one of (((1))) to (((9))); and
an optical transmission unit that transmits light output from the surface emitting semiconductor laser.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A surface emitting semiconductor laser comprising:
a substrate;
a first semiconductor multilayer film reflective mirror stacked on the substrate;
a second semiconductor multilayer film reflective mirror that includes a current confinement layer and is stacked on the first semiconductor multilayer film reflective mirror; and
a light emitting layer that is disposed between the first semiconductor multilayer film reflective mirror and the second semiconductor multilayer film reflective mirror, emits light, and is configured by alternately stacking a quantum well layer containing at least In, Ga, and As and a barrier layer, in which a thickness of the quantum well layer is thinner than a critical film thickness by a predetermined margin.

2. The surface emitting semiconductor laser according to claim 1,
wherein a thickness of the barrier layer is equal to or less than the critical film thickness.

3. The surface emitting semiconductor laser according to claim 1,
wherein the margin is equal to or more than 4.0 nm.

4. The surface emitting semiconductor laser according to claim 3,
wherein the margin is equal to or more than 4.4 nm.

5. The surface emitting semiconductor laser according to claim 1,
wherein an In composition of the quantum well layer is equal to or more than 28%.

6. The surface emitting semiconductor laser according to claim 2,
wherein an In composition of the quantum well layer is equal to or more than 28%.

7. The surface emitting semiconductor laser according to claim 1,
wherein the thickness of the quantum well layer is thinner than a thickness of the barrier layer.

8. The surface emitting semiconductor laser according to claim 2,
wherein the thickness of the barrier layer is equal to or more than 4.0 nm.

9. The surface emitting semiconductor laser according to claim 1,
wherein the thickness of the quantum well layer is within +30% of a thickness of the barrier layer.

10. The surface emitting semiconductor laser according to claim 1,
wherein the quantum well layer is an InGaAs quantum well layer.

11. An optical transmission apparatus comprising:
the surface emitting semiconductor laser according to claim 1; and
an optical transmission unit that transmits light output from the surface emitting semiconductor laser.
